(19) United States
(12) Patent Application Publication
(10) Pub. No.: US 2007/0133073 A1
(43) Pub. Date: Jun. 14, 2007

(54) Information processing apparatus, computer program product and preview image display method

(76) Inventors: Haruo Shida, Kanagawa (JP); Takashi Yano, Tokyo (JP); Tetsuya Sakayori, Tokyo (JP); Junichi Takami, Kanagawa (JP); Yoshinaga Kato, Kanagawa (JP); Yoshifumi Sakuramata, Tokyo (JP); Iwao Saeki, Kanagawa (JP)

Correspondence Address: COOPER & DUNHAM, LLP, 1185 AVENUE OF THE AMERICAS, NEW YORK, NY, 10036, US

(21) Appl. No.: 11/635,220

(22) Filed: Dec. 6, 2006

(30) Foreign Application Priority Data
Dec. 13, 2005 (JP) 2005-359379
Oct. 17, 2006 (JP) 2006-282218

(51) Int. Cl. G03F 3/10

(52) U.S. Cl. 358/527

(57) ABSTRACT

An information processing apparatus includes a receiving unit that receives designation of a first processing and a second processing to be performed on an image created from image data and displayed on a display unit; a simple-preview generating unit that generates a simple preview image by performing the first processing with respect to the image displayed on the display unit; a simple-preview display unit that displays the simple preview image on the display unit; a preview generating unit that generates a preview image by performing the second processing with respect to the image data; and an image replacing unit that overwrites the preview image on the simple preview image on the display unit.

### CROSS-REFERENCE TO RELATED APPLICATIONS

The present document incorporates by reference the entire contents of Japanese priority documents, 2005-359379 filed in Japan on Dec. 13, 2005 and 2006-282218 filed in Japan on Oct. 17, 2006.

### BACKGROUND OF THE INVENTION

1. Field of the Invention

The present invention relates to an information processing apparatus, a computer program product, and a preview image display method.

2. Description of the Related Art

Recently, scanners that scan images of documents, copiers that print the images scanned by the scanners, printers or facsimiles that print externally-input image data, and so-called MFPs (multi function peripheral) that include a combination of these functions, are being employed widely.

In a multi function peripheral, a user can make settings related to various functions, for example, a setting related to image processing such as margin sizes, and a setting related to processing such as stamp printing, stapling, and punching.

However, in conventional multi function peripherals, once copy-printing is started with such settings related to finishing being made, a finished state of the print image cannot be confirmed until a result of printing is obtained. For example, in a finished state in which punch holes have been made, even when the punched holes and an output image are positionally superimposed, this result is unknown until the printout is actually obtained. Hence, this printing may end in failure, and paper can be wasted.

To solve this problem, Japanese Patent Application Laid-Open No. 2001-67347 proposes an information processing apparatus that displays a preview image of a finished state, which is an image of a pre-scanned document on which processing designated by various functions, such as finishing, is performed before an actual copy-printing operation, and that can change settings of printing as required.

At the time of performing printing by making various function-settings on a preview displayed on an operation unit of the multi function peripheral, displaying another preview image that reflects the thus-made settings, and printing after the finished state has been confirmed, the finished state is desirably similar to its actual printout. However, since original image data is first applied with the settings having been made on the preview image, and then the settings-reflected preview image is generated and displayed based on the processed image data, processing time becomes long.

Japanese Patent Application Laid-Open No. 2002-204365 proposes a method of creating, in advance, a plurality of preview images corresponding to setting data sets that are respectively associated with adjustments in image quality, thereby speedily displaying a preview that reflects setting changes.

However, because the preview images corresponding to setting data sets that are respectively associated with adjustments in image quality must be created and stored in a storage unit in advance, the method proposed in Japanese Patent Application Laid-Open No. 2002-204365 requires a large-capacity memory and a high-speed CPU (central processing unit), which increases cost. In addition, it is ineffective to create preview images corresponding to setting data sets in advance that are respectively associated with adjustments in image quality or various functions.

### SUMMARY OF THE INVENTION

It is an object of the present invention to at least partially solve the problems in the conventional technology.

According to an aspect of the present invention, an information processing apparatus includes a receiving unit that receives designation of a first processing and a second processing to be performed on an image created from image data and displayed on a display unit; a simple-preview generating unit that generates a simple preview image by performing the first processing with respect to the image displayed on the display unit; a simple-preview display unit that displays the simple preview image on the display unit; a preview generating unit that generates a preview image by performing the second processing with respect to the image data; and an image replacing unit that overwrites the preview image on the simple preview image on the display unit.

According to another aspect of the present invention, an information processing method includes receiving designation of various types of a first processing and a second processing to be performed on an image created from image data and displayed on a display unit; first generating including generating a simple preview image by performing the first processing with respect to the image displayed on the display unit; displaying the simple preview image generated at the first generating on the display unit; second generating including generating a preview image by performing the second processing with respect to the image data; and overwriting the preview image generated at the second generating on the simple preview image on the display unit.

According to still another aspect of the present invention, a computer program product comprises a computer-readable recording medium having stored therein a plurality of computer-executable commands that cause a computer execute the above method.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a functional block diagram of a multi function peripheral according to a first embodiment of the present invention;

FIG. 2 is a schematic of an example of finished data generated by the multi function peripheral shown in FIG. 1;

FIG. 3 is a schematic for explaining flow of data during a preview-image display processing;

FIG. 4 is a top view of an operation/display unit according to a second embodiment of the present invention; and

FIG. 5 is a flowchart of a preview-image switching processing.

### DETAILED DESCRIPTION OF THE PREFERRED EMBODIMENTS

Exemplary embodiments of the present invention will be explained in detail below with reference to the accompanying drawings.

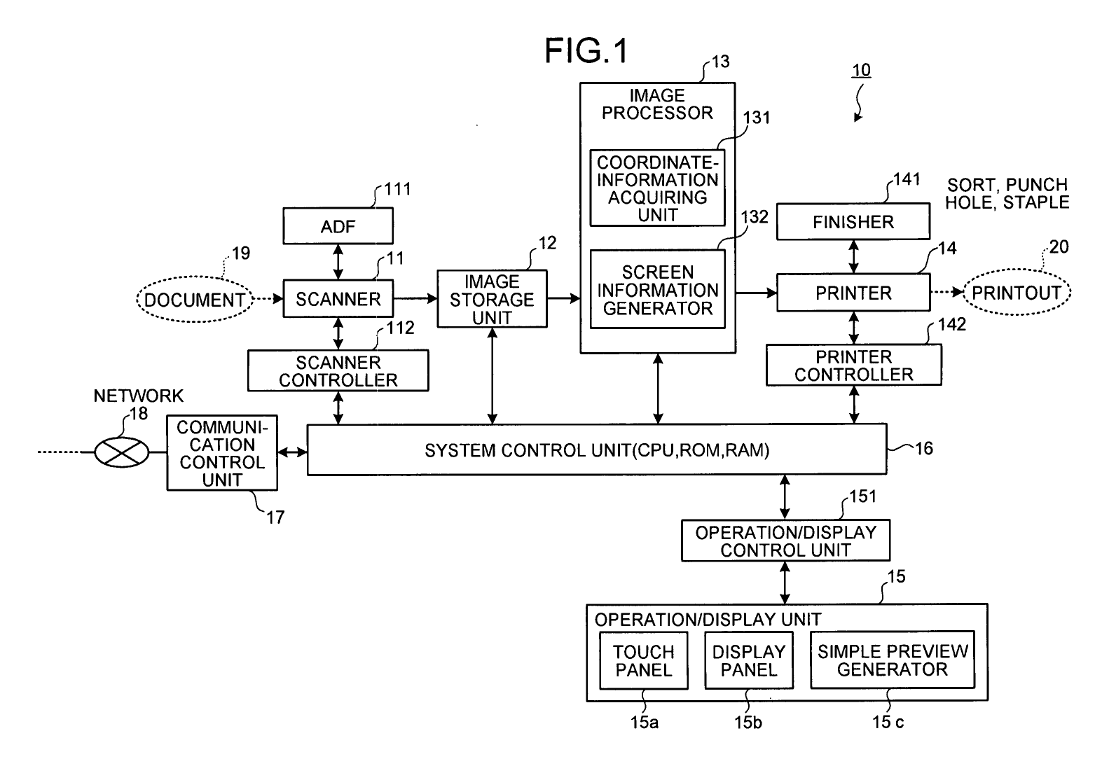

A first embodiment of the present invention will be described with reference to FIGS. 1 to 3. The first embodiment relates to a multi function peripheral as an information processing apparatus. The multi function peripheral has a combination of a copying function, a facsimile (FAX) function, a print function, a scanner function, a function for distributing an image acquired by the scanner function, the print function, or the FAX function, and the like.

FIG. 1 is a functional block diagram of a multi function peripheral 10 according to the first embodiment. The multi function peripheral 10 includes a scanner 11, an automatic document feeder (ADF) 111, a scanner controller 112, an image storage unit 12, an image processor 13, a printer 14, a printer controller 142, a finisher 141, an operation/display unit 15, an operation/display control unit 151, a system control unit 16, and a communication control unit 17. The multi function peripheral 10 is connected to a network 18 via the communication control unit 17. The multi function peripheral 10 reads an image of a document 19, performs image processing on the image, and then outputs the processed image as a printout 20.

The system control unit 16 is connected to each of the constituents, and controls the multi function peripheral 10. For example, the system control unit 16 controls provision of information on a scanning area appropriate for a selected sheet size to the scanner 11. The system control unit 16 includes a CPU (not shown), a read only memory (ROM) (not shown), a random access memory (RAM) (not shown), and the like. The system control unit 16 executes various types of processing by making the CPU operate according to a computer program stored in the ROM, while using a work area in the RAM.

The computer program to be executed by the multi function peripheral 10 can be provided in the form of a file of an installable or executable format, stored in a computer-readable recording medium, such as a CD-ROM, a flexible disk (FD), a CD-R, and a digital versatile disk (DVD). The CPU of the system control unit 16 reads the computer program from the recording medium, and loads the computer program on a main memory device (not shown), thereby making the multi function peripheral 10 implement various functions. Alternatively, the computer program can be stored in a computer connected to the network 18 such as the Internet, so that the computer program is provided through downloading via the network. As another alternative, the computer program can be provided or distributed via a network such as the Internet.

The communication control unit 17 is connected to the network 18, such as a local area network (LAN) or the Internet, and exchanges image data, control data, and the like, with another device connected to the network using a communication protocol.

The scanner controller 112 controls the scanner 11 upon receipt of a command from the system control unit 16.

Under control of the scanner controller 112, the scanner 11 converts an image of the document 19 into digital image data. The ADF 111 can sequentially feed one page of a set document at a time onto a reading position of the scanner 11. In other words, by employing the ADF 111, the scanner 11 can automatically and sequentially read each page of a document containing a plurality of pages. The ADF 111 can be configured to feed to the scanner 11 a one-sided document or a two-sided document. A one-sided document is a document having printing on one side of a sheet, while the two-sided document is a document having printing on both sides of a sheet. When handling two-sided documents, a mechanism for turning the document is required.

The image storage unit 12 is a buffer memory that temporarily stores image data read by the scanner 11, image data externally input via the network 18, and the like, upon receipt of a command from the system control unit 16. The multi function peripheral 10 can form an image by processing image data read by the scanner 11 provided in the multi function peripheral 10 or image data externally input via the network 18, or by another method.

Upon receipt of a command from the system control unit 16, the image processor 13 performs γ correction or MTF (modulation transfer function) correction on multivalue data, which are supplied from the scanner 11 and temporarily stored in the image storage unit 12. Thereafter, the image processor 13 performs tone processing, such as slicing and dithering, on the data, thereby converting the data into binary (or multi-level) data. The image processor 13 further performs various types of processing corresponding to functions set by the user. Examples of the processing include image processing (such as zoom-in and zoom-out, adjustment of density, and adjustment of colors),image area editing (such as deletion, moving, and reversing of a target area), layout processing (such as two-sided or one-sided printing, combined printing, and margin size adjustment), and generation of finished data which is preview image data of a finished state.

The image processor 13 includes a coordinate-information acquiring unit 131 and a screen information generator 132. The coordinate-information acquiring unit 131 acquires coordinate information relating to an input image stored in the image storage unit 12. The screen information generator 132 processes the input image data according to settings designated by various items having been input for the image data, thereby generating expected finished-image information that includes finished data (preview image), to which various settings have been applied. The finished data (preview image) are to be displayed on a display panel 15b, to be described later. The reason for referring to information generated by the screen information generator 132 as the expected finished-image information is, as will be described in the following, that the screen information generator 132 generates finished data to be printed and input screen information. The input screen information is information for an input screen of menu items, which are related to the finished data, on a setting screen. The finished data and the input screen information are collectively called “expected finished-image information”.

The printer controller 142 controls the printer 14 upon receipt of a command from the system control unit 16.

The printer 14, which is controlled by the printer controller 142 utilizes an electrophotographic technology of deflecting an optical beam to perform scanning according to an image data processed by the image processor 13, developing a latent image formed on a photosensitive member using toner, transferring the thus-formed toner image onto a transfer sheet, and performing fixing thereon. Other than an electrophotographic system, an ink-jet system, a dye sublimation transfer system, a silver halide photography system, a direct thermographic recording system, a thermofusible transfer system, or other various systems can be employed as a printing method for the printer 14.

The finisher 141 is connected to the printer 14. Upon receipt of settings automatically input or input by a user, the finisher 141 performs finishing processing, such as sorting, stamp-printing, stapling, and punching. The sorting is processing of sorting the printout 20 on which printing is performed based on the number of copies or pages. The stamp-printing is processing of printing a predetermined stamp on a printed medium. The stapling is processing of aligning plural sheets of printed medium and binding them with a staple. The punching is processing of punching holes used for fastening plural sheets of printed medium into a binder or a file.

The operation/display control unit 151 controls input and output of the operation/display unit 15 upon receipt of a command from the system control unit 16. For example, the operation/display control unit 151 controls an output of data processed by the image processor 13 to a touch panel 15a and a display panel 15b provided on the operation/display unit 15. More specifically, the operation/display control unit 151 makes the display panel 15b display finished data according to expected finished-image information having been generated. The operation/display control unit 151 also controls input from the touch panel 15a. While the display panel 15b and the touch panel 15a are illustrated to be independent from each other in the drawings, the panels 15b and 15a are integrally configured in the first embodiment.

The touch panel 15a electrically or magnetically detects a position at which the panel is touched by a pointer. As a pointing unit (not shown) for the touch panel 15a, human finger tips, a stylus pen, or another touch-input device (hereinafter, a “pointer”) can be employed. More specifically, a user touches the touch panel 15a using such a pointer, thereby inputting various items including those on print settings.

While the first embodiment describes an example in which input is provided by touching the touch panel 15a, embodiments of the first invention are not necessarily limited to input by touching. For example, the operation/display unit 15 can include, in addition to the touch panel 15a, hard keys that provide an input upon receipt of physical pushdown of a key by an operator, and issue an instruction to start printing, and the like. The display panel 15b can alternatively be a dedicated display device provided in the multi function peripheral 10.

Under control of the operation/display control unit 151, the operation/display unit 15 receives input of settings through the touch panel 15a, and displays setting screen menu items on the display panel 15b, which is a display unit. The menu items are used for making settings of finished data and finishing operation.

The operation/display unit 15 is provided for displaying functions to be implemented by the multi function peripheral 10, in the form of setting screen menu items, and receiving settings that are selected from among the thus-displayed menu items and input by the user (function-setting receiver). More specifically, when a pointer touches the touch panel 15a in an area where an item can be selected, the operation/display control unit 151 detects the coordinates of the thus-pressed position. When the coordinates are detected to fall within the area where an item can be selected, the operation/display control unit 151 assumes the touching as an input of the item. For example, the operation/display unit 15 receives settings on reading conditions for the scanner 11 that varies depending on a status of a document, the image processor 13 that performs processing, such as image quality adjustment of read image data, print conditions for printing performed by the printer 14, and the finisher 141 that performs finishing, such as sorting, stapling, and punching, on a printout.

Upon receipt of various settings as described above via the operation/display control unit 151, the system control unit 16 reflects the settings requested by the image processor 13 on original image data stored in the image storage unit 12, thereby creating finished data (preview image), and transmits the data to the operation/display unit 15, and displays the data.

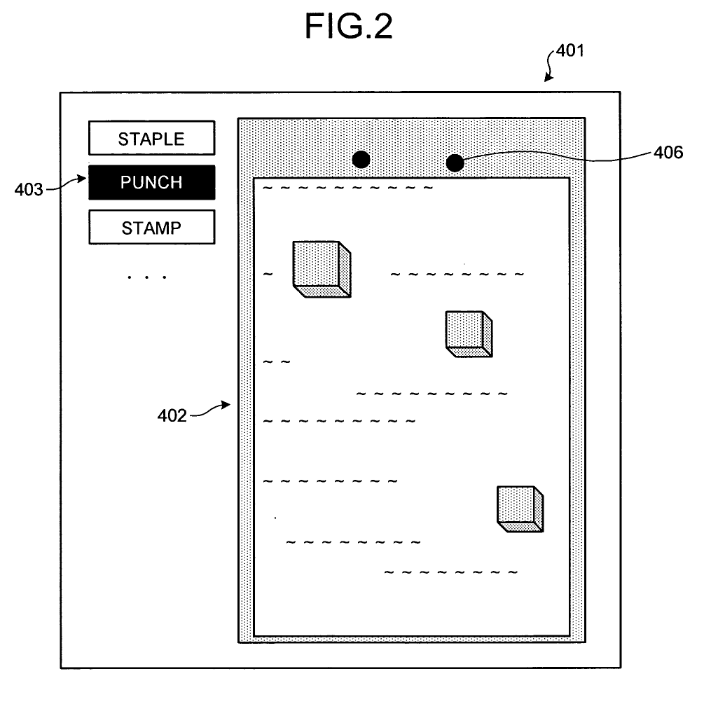

FIG. 2 is a schematic of an example of finished data generated by the multi function peripheral 10 from the input image data. Finished data 402 and setting processing items 403 are displayed inside a display area 401 on the touch panel 15a. When the operator touches the touch panel 15a with a pointer while checking the finished data displayed on the display panel 15b, the touch panel 15a receives input of positional information that represents a spatial position in a displayed print preview of finished data. Upon receipt of the input, the coordinate-information acquiring unit 131 analyzes the positional information having been input by the touch panel 15a, and acquires the coordinate information of the position on the image touched by the pointer.

With this configuration, it is possible to display the finished data (preview image) 402 on the display panel 15b of the operation/display unit 15 of the multi function peripheral 10 before an actual copy-printing operation. In other words, it is possible to perform actual printing after visually confirming the finished data.

When printing by the multi function peripheral 10 is performed by making various function-settings on a preview displayed on the operation/display unit 15, displaying the finished data (preview image) 402 that reflects the thus-made settings on the display panel 15b, and printing after the finished state has been confirmed, the finished state is desirably similar to its actual printout. However, since original image data is first applied with the settings having been made on the finished data (preview image) 402, and then the settings-reflected finished data (preview image) 402 are generated and displayed based on the processed image data, processing time becomes long.

Therefore, in the first embodiment, when displaying on the display panel 15b the finished data (preview image) 402 that reflects settings having been made on a displayed preview, as shown in FIG. 1, a simple preview generator 15c generates a simple finished data (preview image) 402. The simple preview generator 15c, which is provided in the operation/display unit 15, generates a simple preview. More specifically, the simple preview generator 15c processes the finished data (preview image) 402, and does not process, for example, image data actually read by the scanner 11.

More specifically, when punching is selected as a finishing operation, simple (tentative) finished data (preview image) 402 are obtained by superimposing two solid black circular marks 406 representing punching holes on detailed finished data (preview image) 402 having already been generated and displayed on the display panel 15b. Accordingly, since the size of data to be processed is remarkably reduced as compared with when the detailed finished data (preview image) 402 are re-generated from the original image data while adding punched holes thereto, the finished data (preview image) 402 can be displayed speedily. The simple preview generator 15c is realized by software processing using a CPU (not shown) provided in the operation/display unit 15.

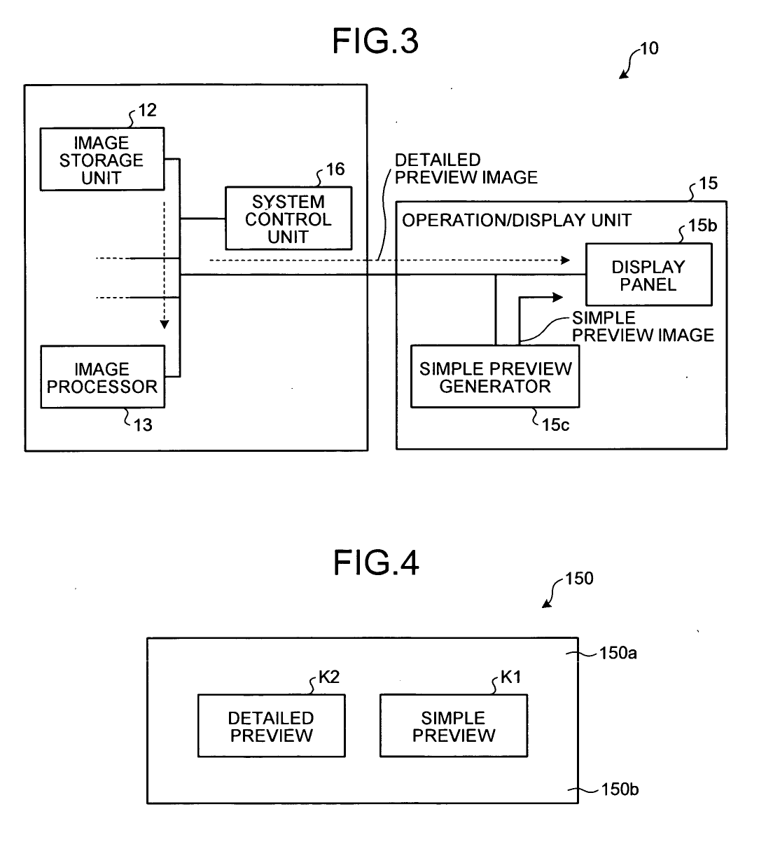

That is, in the first embodiment, when various function-settings are made on a preview displayed on the operation/display unit 15, and the finished data (preview image) 402 that reflect the settings are displayed on the display panel 15b, as shown in FIG. 3, the simple preview generator 15c generates the simple (tentative) finished data (preview image) 402, and speedily displays the data on the display panel 15b (simple-preview display unit). After settings requested from the system control unit 16 are applied to the original image data and hence the settings-reflected finished data (preview image) 402 have been generated, the finished data (preview image) 402 displayed on the display panel 15b are replaced therewith (image replacing unit). With this configuration, a preview can be displayed speedily.

The configuration of making the simple preview generator 15c generate and display the simple finished data (preview image) 402 before displaying the detailed finished data (preview image) 402 is effective when settings are made to make the image processor 13 perform adjustment of image quality (e.g., color adjustment) on the image data. Since the image quality adjustment can put a high load on the system and requires a long time, it is quite effective to process and display the simple finished data (preview image) 402 speedily before displaying the detailed finished data (preview image) 402 in view of reducing a waiting time for the user.

As described above, according to the first embodiment, upon receipt of a request to process the preview image 402 displayed on the display panel 15b, the simple preview generator 15c generates the simple (tentative) preview image 402 that tentatively shows a result of application of the thus-received processing to the preview image 402, and speedily displays the simple preview image 402 on the display panel 15b. After the detailed preview image 402 has been generated by applying the received processing, which is to be performed on the original image data, the simple (tentative) preview image 402 displayed on the display panel 15b is replaced with the detailed preview image 402. Accordingly, since a preview image is displayed speedily by first using a light-load method, and thereafter replacing the image with a detailed preview image that requires long processing time, speed up of preview display is realized efficiently, thereby minimizing user's dissatisfaction even when a detailed preview is to be displayed.

The simple preview generator 15c is provided in the operation/display unit 15 in the first embodiment. However, if the CPU of the operation/display unit 15 is lower in processing capacity, the simple preview generator 15c can be formed using a main CPU of the system control unit 16 that generally has higher processing capacity.

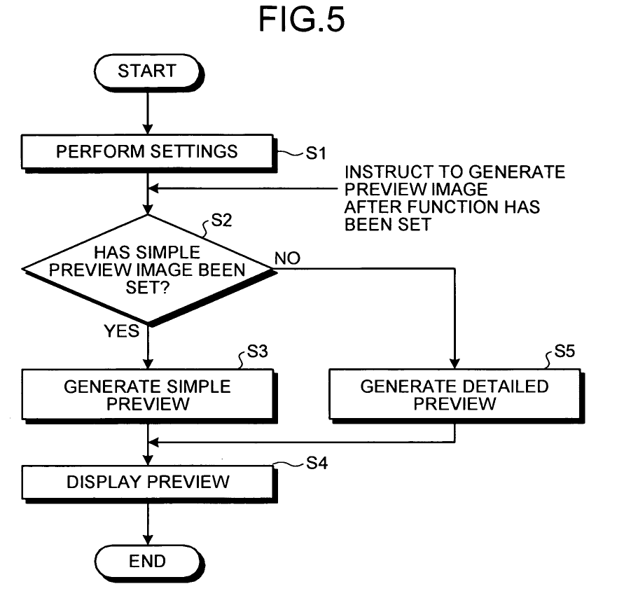

A second embodiment of the present invention will be described with reference to FIGS. 4 and 5. FIG. 4 depicts an operation/display unit 150 according to the second embodiment that can be used instead of the operation/display unit 15 in the multi function peripheral 10. The rest of the configuration of the multi function peripheral according to the second embodiment is the same as that of the multi function peripheral 10.

In the second embodiment, as shown in FIG. 4, keys K1 and K2 for selecting a simple preview image or a detailed preview image as the finished data (preview image) 402 to be displayed on a display panel 150b of the operation/display unit 150 are displayed, and hence either the key K1 or K2 can be selected using a touch panel 150a. More specifically, when the key K2 (cancellation notifying unit) for selecting a detailed preview image as the finished data (preview image) 402 to be displayed on the display panel 150b is operated, generation of a simple (tentative) preview image by the simple preview generator 15c is cancelled (simple-preview generation-canceling unit).

Preview-image switching processing, which is characteristic processing of the invention, will be described next. The preview-image switching processing is performed through operation of the CPU of the system control unit 16 according to a computer program stored in the ROM.

FIG. 5 is a flowchart of the preview-image switching processing. As shown in FIG. 5, the preview-image switching processing is effected on a condition that either the key K1 for selecting a simple preview image or the key K2 for selecting a detailed preview image has been operated to thus make settings (step S1). Upon receipt of a command to generate a preview image issued after the functions have thus been set, when the simple preview image has been set (YES at step S2), the simple preview generator 15c of the operation/display unit 150 is controlled via the operation/display control unit 151, to thus generate the simple finished data (preview image) 402 (step S3). The generated simple finished data (preview image) 402 are displayed on the display panel 150b (step S4).

On the other hand, when the detailed preview image has been set (NO at step S2), the detailed finished data (preview image) 402 are generated (step S5), and the generated detailed finished data (preview image) 402 are displayed on the display panel 150b (step S4).

As described above, according to the second embodiment, because generation of a simple preview image can be cancelled, usability is enhanced.

While, in the second embodiment, preview images are switched through key input using the key K1 or K2, the invention is not limited thereto, and can be configured to perform switching of preview images as determined by settings. For example, when settings that require punching, stapling, or the like, for which positional information is important but which has no influence on printout states are made, a simple preview is generated. When settings for which printout states (color adjustment, or the like) are important are made, a detailed preview image is generated. Alternatively, since processing such as color adjustment can place a high load on the system and requires a long time, the switching can be performed such that a simple preview image is generated for settings that place a high load, whereas a detailed preview image is generated for settings that place a light load.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. An information processing apparatus comprising:
a receiving unit that receives designation of a first processing and a second processing to be performed on an image created from image data and displayed on a display unit;
a simple-preview generating unit that generates a simple preview image by performing the first processing with respect to the image displayed on the display unit;
a simple-preview display unit that displays the simple preview image on the display unit;
a preview generating unit that generates a preview image by performing the second processing with respect to the image data; and
an image replacing unit that overwrites the preview image on the simple preview image on the display unit.

2. The information processing apparatus according to claim 1, wherein the simple-preview generating unit is realized by software processing using a central processing unit of an operation/display unit.

3. The information processing apparatus according to claim 1, wherein the simple-preview generating unit is realized by software processing using a central processing unit of a system control unit that controls the entire apparatus.

4. The information processing apparatus according to claim 1, further comprising a canceling unit that cancels generation of the simple preview image by the simple-preview generating unit.

5. The information processing apparatus according to claim 4, further comprising a cancellation notifying unit that specifies whether to perform cancellation of generation of the simple preview image, wherein
the canceling unit does not cancel the generation of the simple preview image when the cancellation notifying unit specifies non-cancellation of generation of the simple preview image.

6. The information processing apparatus according to claim 4; wherein the canceling unit determines whether to perform or cancel generation of the simple preview image according to contents of the first processing.

7. A computer program product comprising a computer-readable recording medium having stored therein a plurality of computer-executable commands for displaying a preview image on a display unit, wherein the commands cause a computer execute:
receiving designation of various types of a first processing and a second processing to be performed on an image created from image data and displayed on a display unit;
first generating including generating a simple preview image by performing the first processing with respect to the image displayed on the display unit;
displaying the simple preview image generated at the first generating on the display unit;
second generating including generating a preview image by performing the second processing with respect to the image data; and
overwriting the preview image generated at the second generating on the simple preview image on the display unit.

8. The computer program product according to claim 7, further causing the computer execute canceling generation of the simple preview image at the first generating.

9. The computer program product according to claim 8, further causing the computer execute performing setting whether to perform cancellation of generation of the simple preview image at the canceling, wherein
the canceling includes not canceling the generation of the simple preview image at the first generating when the setting performed at the performing indicate non-cancellation of generation of the simple preview image.

10. The computer program product according to claim 8, wherein the canceling includes canceling generation of the simple preview image at the first generating according to contents of the first processing.

11. An information processing method comprising:
receiving designation of various types of a first processing and a second processing to be performed on an image created from image data and displayed on a display unit;
first generating including generating a simple preview image by performing the first processing with respect to the image displayed on the display unit;
displaying the simple preview image generated at the first generating on the display unit;
second generating including generating a preview image by performing the second processing with respect to the image data; and
overwriting the preview image generated at the second generating on the simple preview image on the display unit.

12. The information processing method according to claim 11, further comprising canceling generation of the simple preview image at the first generating.

13. The information processing method according to claim 12, further comprising performing setting whether to perform cancellation-of generation of the simple preview image at the canceling, wherein
the canceling includes not canceling the generation of the simple preview image at the first generating when the setting performed at the performing indicate non-cancellation of generation of the simple preview image.

14. The information processing method according to claim 12, wherein the canceling includes canceling generation of the simple preview image at the first generating according to contents of the first processing.
